(19) United States
(12) Patent Application Publication
(10) Pub. No.: US 2025/0252228 A1
(43) Pub. Date: Aug. 7, 2025

(54) UNCERTAINTY QUANTIFICATION

(71) Applicant: Lockheed Martin Corporation, Bethesda, MD (US)

(72) Inventors: Spenser Warren Stone, Dallas, TX (US); Corey Benjamin Mutnik, Plantation, FL (US); Bruno F. Janota, Moorestown, NJ (US); Kaitlyn Christine Bedard, Tolland, CT (US)

(21) Appl. No.: 18/615,188

(22) Filed: Mar. 25, 2024

Related U.S. Application Data
(63) Continuation-in-part of application No. 18/433,702, filed on Feb. 6, 2024.

(51) Int. Cl. G06F 30/20

(52) U.S. Cl. CPC G06F 30/20

(57) ABSTRACT

According to an embodiment, a computer-implemented method for operating a system for uncertainty quantification (UQ) of imperial data, a simulation of a mathematical model or for testing a technical system includes the following steps: (i) defining simulation output parameters and an accuracy range; (ii) uploading simulation output data and configuration file; (iii) searching for and applying a variety of surrogate models via automation; (iv) determining the reliability of the selected model; (v) providing a report; and (vi) using the validated model to generate new data points.

### CROSS REFERENCE TO RELATED APPLICATIONS

This application is a continuation of U.S. application Ser. No. 18/433,702, filed Feb. 6, 2024, the contents of each are incorporated herein by reference.

### TECHNICAL FIELD

This disclosure relates generally to uncertainty quantification (UQ) systems, and more specifically to an apparatus and a method for determining and/or decreasing uncertainty in parameterized model predictions.

### BACKGROUND

Uncertainty quantification systems may be utilized to calculate and reduce uncertainties for model simulations and technical systems. Uncertainty quantification evaluates the result of a simulation or a measurement of a system behavior with a given uncertainty of input variables, structural variables, uncertainty of the underlying mathematical model and/or system or model parameters.

The uncertainty quantification is carried out using a UQ system, which represents a framework with which an evaluation of input variables, system and model parameters can be carried out for simulation models and other technical systems. Current tools require other users to make selections based on their understanding and judgement.

### BRIEF DESCRIPTION OF THE DRAWINGS

FIG. 1A illustrates an example of a schematic representation of computer system for quantifying uncertainty.

FIG. 1B illustrates the UQ system.

FIG. 2 illustrates a flow chart of a method for operating the UQ system.

FIG. 3 illustrates a flow diagram for performing end to end operations of the UQ system.

### DESCRIPTION OF EXAMPLE EMBODIMENTS

OVERVIEW

The present disclosure is directed to techniques for operating an uncertainty quantification system for carrying out an uncertainty quantification. In particular embodiments, the user specifies one or more initial variables lacking attached uncertainties for the uncertainty quantification system as input.

According to an embodiment, the method also comprises building a surrogate model via an automated application that approximates a relation between the target accuracy range and the initial parameters. The relation may be based off of a standard deviation metric, and the dual objective pareto optimal surrogate model selection process is based on root mean square error and an uncertainty calibration error.

According to another embodiment, the method further comprises performing a statistical inference so that a relation between the initial parameters and the target parameters may be drawn, including a significance level of the initial input variables, and the user interface informs the user of the evaluation metrics and may offer the user to refine the input data via an automated process if the initial relation does not achieve the desired significance level.

According to another embodiment, the system to be modeled may be in the field of (but not limited to) computational fluid dynamics including (but not limited to) a product related to aircraft turbulence, and the layout parameters comprise a frequency (Hz), an angle of attack (deg), a chord length (m), a free-stream velocity (m/s), and a suction side displacement thickness (m), and the target parameters comprise a scaled sound pressure level (dB).

In some embodiments, a Bayesian optimization procedure uses a Tree Parzen Estimator (TPE) and an expected improvement algorithm to select a desired model, often with comparatively fewer iterations than a random search. The process promotes run-time efficiency for optimization for each surrogate and assists model selection with finding the best model with larger grids. The dual objective pareto optimal model selection process is based on root mean square error and an uncertainty calibration area, which balances tradeoff between minimizing model errors and producing efficient uncertainties in line with model coverage.

In some embodiments, the user interface is configured for preparing output data reflecting initial parameter sensitivities based on analyzing a relation between the objective responses and the initial parameters. The sensitivities determined from the surrogate model may capture correlation of several of the layout parameters with one of the target parameters.

According to other embodiments, a computing system for sample augmentation is included to enhance inadequate training samples by providing the model with new training examples that are estimated to have the highest potential impact to the model. Active learning employs Bayesian Optimization to calculate the expected improvement of new points. Interpretation of model output is provided in summary reporting on a user interface with every UQ analysis. The system outputs and explains in-depth a variety of model performance metrics tailored to both the interpolation ability of the model, as well as metrics unique to the uncertainty calibration of the predicted standard deviation. Automated exploratory data analysis is connected to the uncertainty quantification system to promote data discovery and assist the user with making connections about how UQ results are impacted by trends in the data. For example, if no relationship exists between a predictor and targets, automated mechanisms within the system prompt the user with an alert to revisit how the data were generated.

According to other embodiments, an uncertainty quantification system implements a collection of surrogate models that output point-level prediction uncertainty estimates. The models are collectively capable of learning from both homoskedastic and heteroskedastic noise signals from the data.

According to other embodiments, an uncertainty quantification system performs a grid search over hyper-parameter combinations and utilizes data preprocessing. Some embodiments may utilize an optuna active learning process that selects validated surrogate models with comparatively fewer iterations than random grid sampling. The search includes (but is not limited to) predictor variable scaling and variance stabilizing transformations that promote building models that are robust to a variety of use cases in regression modeling (e.g., unstable variance, outlier influence). Hyper-parameter selection is governed by a dual-objective optimization criteria that simultaneously minimizes root mean squared error (RMSE) and uncertainty calibration area. This promotes selection of the model with the most accurate uncertainty bands among models with similar interpolation performance. Model comparison uses rigorous statistical testing methodologies that inform selection of a parsimonious model from among competing alternatives. Population inference acts as a safeguard measure against the possibility of overfitting in the model selection process, especially when confronted with small sample sizes, which is a typical scenario in collected computational fluid dynamics (CFD) data.

Other technical advantages will be readily apparent to one skilled in the art from the following figures, descriptions, and claims. Moreover, while specific advantages have been enumerated above, various embodiments may include all, some, or none of the enumerated advantages.

### EXAMPLE EMBODIMENTS

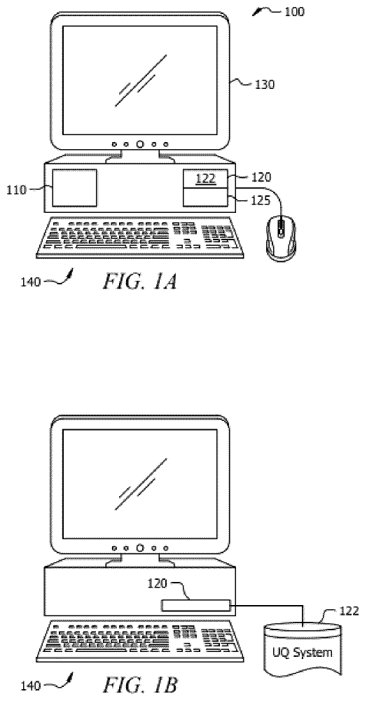

FIG. 1A illustrates an example of a schematic representation of a computer system 100 for quantifying uncertainty in technical models. The computer system 100 comprises a processor unit 110, memory 120, UQ system 122, storage 125, an output device 130 (such as a monitor), and an input device 140 (such as a keyboard and/or a mouse).

FIG. 1B illustrates a UQ system 122. The UQ system may be implemented as a standalone system (where a user may import the library containing statistical methods) or as an automated process. The UQ system 122 can be stored in a program as software code on data memory 120 as shown in FIG. 1A, and can be executed by the processor unit 110.

In particular embodiments, computer system 100 performs one or more steps of one or more methods described or illustrated herein. In particular embodiments, computer system 100 provides functionality described or illustrated herein. In particular embodiments, software running on computer system 100 performs one or more steps of one or more methods described or illustrated herein or provides functionality described or illustrated herein. Particular embodiments include one or more portions of computer system 100. Herein, reference to a computer system may encompass a computing device, and vice versa, where appropriate. Moreover, reference to a computer system may encompass one or more computer systems, where appropriate.

This disclosure contemplates any suitable number of computer systems 100. This disclosure contemplates computer system 100 taking any suitable physical form. As example and not by way of limitation, computer system 100 may be an embedded computer system, a system-on-chip (SOC), a single-board computer system (SBC) (such as, for example, a computer-on-module (COM) or system-on-module (SOM)), a desktop computer system, a laptop or notebook computer system, an interactive kiosk, a mainframe, a mesh of computer systems, a mobile telephone, a personal digital assistant (PDA), a server, a tablet computer system, an augmented/virtual reality device, or a combination of two or more of these. Where appropriate, computer system 100 may include one or more computer systems 100; be unitary or distributed; span multiple locations; span multiple machines; span multiple data centers; or reside in a cloud, which may include one or more cloud components in one or more networks. Where appropriate, one or more computer systems 100 may perform without substantial spatial or temporal limitation one or more steps of one or more methods described or illustrated herein.

As an example, and not by way of limitation, one or more computer systems 100 may perform in real time or in batch mode one or more steps of one or more methods described or illustrated herein. One or more computer systems 100 may perform at different times or at different locations one or more steps of one or more methods described or illustrated herein, where appropriate. In particular embodiments, computer system 100 includes a processor 110, memory 120, storage 125, an output device 130, and an input device 140. Although this disclosure describes and illustrates a particular computer system having a particular number of particular components in a particular arrangement, this disclosure contemplates any suitable computer system having any suitable number of any suitable components in any suitable arrangement.

In particular embodiments, processor 110 includes hardware for executing instructions, such as those making up a computer program. As an example, and not by way of limitation, to execute instructions, processor 110 may retrieve (or fetch) the instructions from an internal or external register, cache, memory 120, UQ system 122, or storage 125; decode and execute them; and then write one or more results to an internal register, an internal cache, memory 120, UQ system 122, or storage 125. In particular embodiments, processor 110 may include one or more internal caches for data, instructions, or addresses. This disclosure contemplates processor 110 including any suitable number of any suitable internal caches, where appropriate. As an example, and not by way of limitation, processor 110 may include one or more instruction caches, one or more data caches, and one or more translation lookaside buffers (TLBs). Instructions in the instruction caches may be copies of instructions in memory 120 or storage 125, and the instruction caches may speed up retrieval of those instructions by processor 110.

Data in the data caches may be copies of data in memory 120 or storage 125 for instructions executing at processor 110 to operate on; the results of previous instructions executed at processor 110 for access by subsequent instructions executing at processor 110 or for writing to memory 120 or storage 125; or other suitable data.

In the illustrated embodiment, memory 120 may include UQ system 122 (as shown in FIG. 1A) or UQ system 122 may be a standalone system (as shown in FIG. 1B). UQ system 122 receives initial variables or test parameters for testing computer system 100. These variables are inputs according to a specification of one or more parameters. For example, the variables may include regression variables. This includes (but is not limited to) variables related to housing costs, income, land area, lift coefficients, speed, etc., The variables may be based on any dataset where there is a correlation between input and output variables as well as datasets where there is no correlation between variables. UQ system 122 analyzes the variables and provides output metrics that are stored in the data memory 120 of the computer system 100 as the results of the analysis. Outputs may include (but are not limited to) code documentation, graphical representations of input data with respective correlations and distributions, accuracy metrics, calibration metrics, sensitivity analysis, partial dependence plots, uncertainty calibration area diagnostics, csv file containing active learning data, cross validation design, confidence and prediction intervals, coverage plot, coverage percentage, surrogate model, summary report, and comprehensive report.

The data caches may speed up read or write operations by processor 110. The TLBs may speed up virtual-address translation for processor 110. In particular embodiments, processor 110 may include one or more internal registers for data, instructions, or addresses. This disclosure contemplates processor 110 including any suitable number of any suitable internal registers, where appropriate. Where appropriate, processor 110 may include one or more arithmetic logic units (ALUs); be a multi-core processor; or include one or more processors 110. Although this disclosure describes and illustrates a particular processor, this disclosure contemplates any suitable processor.

In particular embodiments, memory 120 includes main memory for storing instructions for processor 110 to execute or data for processor 110 to operate on. In some embodiments, the memory 120 may be integral to or accompanied on the processor 110 (e.g., memory 120 is on the same chip as processor 110). As an example, and not by way of limitation, computer system 100 may load instructions from storage 125 or another source (such as, for example, another computer system 100) to memory 120. Processor 110 may then load the instructions from memory 120 to an internal register or internal cache. To execute the instructions, processor 110 may retrieve the instructions from the internal register or internal cache and decode them. During or after execution of the instructions, processor 110 may write one or more results (which may be intermediate or final results) to the internal register or internal cache. Processor 110 may then write one or more of those results to memory 120. In particular embodiments, processor 110 executes only instructions in one or more internal registers or internal caches or in memory 120 (as opposed to storage 125 or elsewhere) and operates only on data in one or more internal registers or internal caches or in memory 120 (as opposed to storage 125 or elsewhere).

One or more memory buses (which may each include an address bus and a data bus) may couple processor 110 to memory 120. Bus may include one or more memory buses, as described below. In particular embodiments, one or more memory management units (MMUs) reside between processor 110 and memory 120 and facilitate accesses to memory 120 requested by processor 110. In particular embodiments, memory 120 includes random access memory (RAM). This RAM may be volatile memory, where appropriate. Where appropriate, this RAM may be dynamic RAM (DRAM) or static RAM (SRAM). Moreover, where appropriate, this RAM may be single-ported or multi-ported RAM. This disclosure contemplates any suitable RAM. Memory 120 may include one or more memories 120, where appropriate. Although this disclosure describes and illustrates particular memory, this disclosure contemplates any suitable memory.

In particular embodiments, storage 125 includes mass storage for data or instructions. As an example, and not by way of limitation, storage 125 may include a hard disk drive (HDD), a floppy disk drive, flash memory, an optical disc, a magneto-optical disc, magnetic tape, or a Universal Serial Bus (USB) drive or a combination of two or more of these. Storage 125 may include removable or non-removable (or fixed) media, where appropriate. Storage 125 may be internal or external to computer system 100, where appropriate. In particular embodiments, storage 125 is non-volatile, solid-state memory. In particular embodiments, storage 125 includes read-only memory (ROM). Where appropriate, this ROM may be mask-programmed ROM, programmable ROM (PROM), erasable PROM (EPROM), electrically erasable PROM (EEPROM), electrically alterable ROM (EAROM), or flash memory or a combination of two or more of these. This disclosure contemplates mass storage 125 taking any suitable physical form. Storage 125 may include one or more storage control units facilitating communication between processor 110 and storage 125, where appropriate. Where appropriate, storage 125 may include one or more storages 125. Although this disclosure describes and illustrates particular storage, this disclosure contemplates any suitable storage.

In particular embodiments, I/O interface 140/130 includes hardware, software, or both, providing one or more interfaces for communication between computer system 100 and one or more I/O devices. Computer system 100 may include one or more of these I/O devices, where appropriate. One or more of these I/O devices may enable communication between a person and computer system 100. As an example, and not by way of limitation, an I/O device may include a keyboard, keypad, microphone, monitor, mouse, printer, scanner, speaker, still camera, stylus, tablet, touch screen, trackball, video camera, another suitable I/O device or a combination of two or more of these. An I/O device may include one or more sensors. This disclosure contemplates any suitable I/O devices and any suitable I/O interfaces 140/130 for them. Where appropriate, I/O interface 140/130 may include one or more device or software drivers enabling processor 110 to drive one or more of these I/O devices. I/O interface 140/130 may include one or more I/O interfaces 140/130, where appropriate. Although this disclosure describes and illustrates a particular I/O interface, this disclosure contemplates any suitable I/O interface.

In particular embodiments, communication interface includes hardware, software, or both providing one or more interfaces for communication (such as, for example, packet-based communication) between computer system 100 and one or more other computer systems 100 or one or more networks. As an example, and not by way of limitation, communication interface may include a network interface controller (NIC) or network adapter for communicating with an Ethernet or other wire-based network or a wireless NIC (WNIC) or wireless adapter for communicating with a wireless network, such as a WI-FI network. This disclosure contemplates any suitable network and any suitable communication interface for it.

As an example, and not by way of limitation, computer system 100 may communicate with an ad hoc network, a personal area network (PAN), a local area network (LAN), a wide area network (WAN), a metropolitan area network (MAN), or one or more portions of the Internet or a combination of two or more of these. One or more portions of one or more of these networks may be wired or wireless. As an example, computer system 100 may communicate with a wireless PAN (WPAN) (such as, for example, a BLUETOOTH WPAN), a WI-FI network, a WI-MAX network, a cellular telephone network (such as, for example, a Global System for Mobile Communications (GSM) network), or other suitable wireless network or a combination of two or more of these. Computer system 100 may include any suitable communication interface for any of these networks, where appropriate. Communication interface may include one or more communication interfaces, where appropriate. Although this disclosure describes and illustrates a particular communication interface, this disclosure contemplates any suitable communication interface.

In particular embodiments, bus includes hardware, software, or both coupling components of computer system 100 to each other. As an example and not by way of limitation, bus may include an Accelerated Graphics Port (AGP) or other graphics bus, an Enhanced Industry Standard Architecture (EISA) bus, a front-side bus (FSB), a HYPERTRANSPORT (HT) interconnect, an Industry Standard Architecture (ISA) bus, an INFINIBAND interconnect, a low-pin-count (LPC) bus, a memory bus, a Micro Channel Architecture (MCA) bus, a Peripheral Component Interconnect (PCI) bus, a PCI-Express (PCIe) bus, a serial advanced technology attachment (SATA) bus, a Video Electronics Standards Association local (VLB) bus, or another suitable bus or a combination of two or more of these. Bus may include one or more buses, where appropriate. Although this disclosure describes and illustrates a particular bus, this disclosure contemplates any suitable bus or interconnect.

Herein, a computer-readable non-transitory storage medium or media may include one or more semiconductor-based or other integrated circuits (ICs) (such, as for example, field-programmable gate arrays (FPGAs) or application-specific ICs (ASICs)), hard disk drives (HDDs), hybrid hard drives (HHDs), optical discs, optical disc drives (ODDs), magneto-optical discs, magneto-optical drives, floppy diskettes, floppy disk drives (FDDs), magnetic tapes, solid-state drives (SSDs), RAM-drives, SECURE DIGITAL cards or drives, any other suitable computer-readable non-transitory storage media, or any suitable combination of two or more of these, where appropriate. A computer-readable non-transitory storage medium may be volatile, non-volatile, or a combination of volatile and non-volatile, where appropriate.

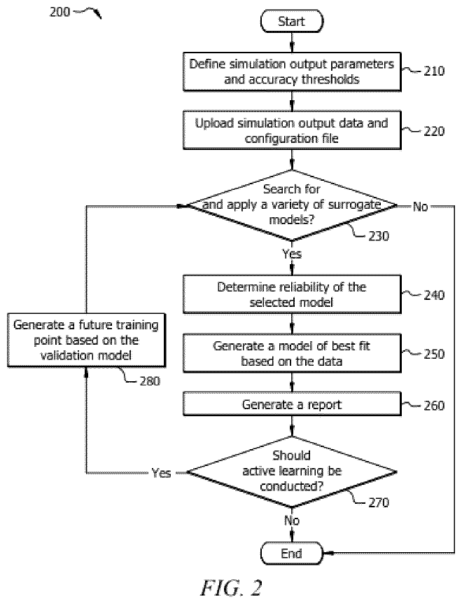

FIG. 2 represents a method for operating the UQ system 122. In order to commence the analysis, the UQ system 122 performs a user interaction process, as described below.

In step 210, the system defines simulation output parameters and an accuracy threshold for evaluating a mathematical model. Depending on the system, the initial variables (which serve as inputs to the uncertainty quantification system) can be physical variables such as frequency and velocity, or geometric variables such as lengths and widths, and the like.

In step 220, the system interfaces with the uncertainty quantification system via a graphical user interface. Simulation output data will be uploaded as an input into the UQ system. Simulation output data may include two files: one data file, which contains any database with inputs (X's) and outputs (Y's); and a configuration file, which contains explicit input specification requirements for the automated uncertainty quantification application (Auto-UQ). Once the appropriate files have been added to Auto-UQ, the upload can begin.

In step 230, the UQ system determines whether to search for and apply a variety of surrogate models. Model database 231 contains surrogate models. The UQ system makes a query in the model database 231 and selects a surrogate model based on the default values from the user interface. For example, the most reliable surrogate models are read out for the default values provided. In this example, reliability is determined based on a probabilistic distribution utilized by the surrogate models. The database contains statistical data on the use of the various types of surrogate models for the specified inputs including accuracy range.

In step 240, the UQ system determines the reliability of the selected model. For example, an automated UQ application, Auto-UQ, in the UQ system may make statistical inferences based on the input data to access reliability. Based on these inferences, the automated UQ application and may then select optimal surrogate models.

In step 250, the UQ system generates a report. The report may include various determinations to facilitate future analysis. For example, the report may include points of uncertainty discovered in the simulation model. Additionally, the report may include future recommended test points by using (but not limited to) active learning procedures such as multi-fidelity extension of Bayesian Optimization (MUMBO). In this example, MUMBO suggests new points to improve the surrogate model. The generated reports allows a user to determine whether Auto-UQ produced an effective surrogate model. The report may also include uncertainty calibration statistics and prediction error statistics. The coverage rate (i.e., the proportion of true simulation points that fall within an uncertainty band for a prediction) indicates the validity of the results.

In step 260, UQ system generates a future test point based on the validated model. After a probabilistic distribution may have been determined for each of the default input values provided, the simulation model or the technical system is evaluated on the basis of the initial input values. Additionally, the validated surrogate model may be used to generate new data points, and the new simulation data points may be inputted into the UQ system manually and the process may begin again at step 210.

Although this disclosure describes and illustrates particular steps of method 200 of FIG. 2 as occurring in a particular order, this disclosure contemplates any suitable steps of method 200 of FIG. 2 occurring in any suitable order. Although this disclosure describes and illustrates an example method for using the Auto-UQ system, including the particular steps of the method of FIG. 2, this disclosure contemplates any suitable method for using Auto-UQ system, including any suitable steps, which may include all, some, or none of the steps of the method of FIG. 2, where appropriate. Although FIG. 2 describes and illustrates particular components, devices, or systems carrying out particular actions, this disclosure contemplates any suitable combination of any suitable components, devices, or systems carrying out any suitable actions.

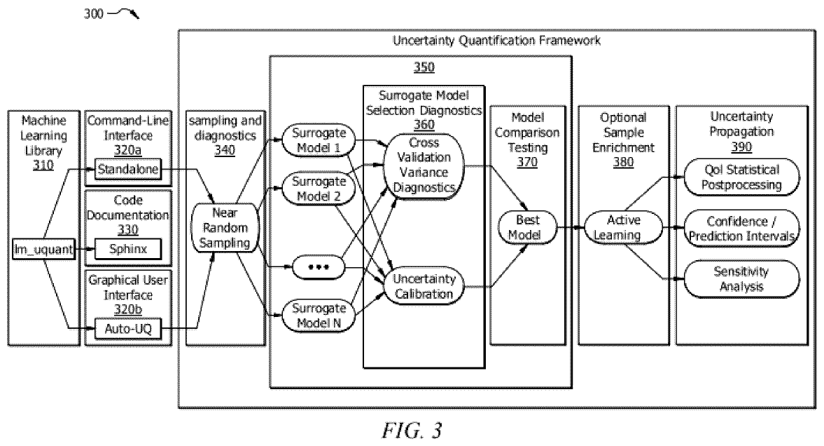

FIG. 3 illustrates a flow diagram 300 for performing end to end operations of the UQ system. Machine Learning Library 310 represents a library containing machine learning code (e.g., a Python library). The library 310 determines which surrogate model is most appropriate for the initial input variables. In the illustrated embodiment, framework 320 uses this code library. Framework 320 may be a standalone framework or an Auto-UQ application. A standalone framework may be executed from a native machine on the desktop, while the Auto-UQ application represents a web-based application that is stored on a remote server and may be accessed via an internet browser. In the illustrated embodiment, a code documenter 330 documents the code.

Framework 320 may then utilize a statistical method 340 for generating a quasi-random sample of parameter values from a univariate statistical probability distribution. For example, statistical method 340 may include (but is not limited to) Latin hypercube sampling (LHS), Monte-Carlo sampling, and fully non-random sampling techniques. Framework 350 may operate with a variety of different surrogate models and optimizes the system based on parameters and comparison metrics. Framework 320 allows for an accurate surrogate model to be determined and selected and removes user bias. Once framework 320 determines an appropriate surrogate model, an active learning candidate point outputs to box 360, which provides the new data point(s) to evaluate next. A cross validation variance diagnostic process runs at box 370, which results in an uncertainty propagation that includes confidence intervals and sensitivity analysis.

Framework 350 may then utilize statistical significance comparisons for selections of the best surrogate model.

If selected to run by the user, Framework 380 may then recommend candidate points for the original simulation to sample at, to increase model fidelity for small samples.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative. Additionally, although this disclosure describes or illustrates particular embodiments as providing particular advantages, particular embodiments may provide none, some, or all of these advantages.

What is claimed is:

1. A method for quantifying uncertainty in computational based models, the method comprising:
receiving, by an uncertainty quantification computing device, input parameters;
performing, by the uncertainty quantification computing device, a statistical analysis to generate a plurality of uncertainty intervals based on the input parameters;
determining, by the uncertainty quantification computing device, whether the input parameters fall within an accuracy range;
generating, by the uncertainty quantification computing device, a report including the plurality of the uncertainty intervals and a future test point recommendation.

2. The method of claim 1, wherein receiving the input parameters further comprises:
defining simulation output parameters and the accuracy range; and
uploading simulation output data and a configuration file.

3. The method of claim 1, wherein performing the statistical analysis to generate the plurality of uncertainty intervals based on the input parameters further comprises utilizing an automated process to select and compare surrogate models.

4. The method of claim 3, wherein the surrogate models further comprise machine learning algorithms.

5. The method of claim 3, wherein utilizing the automated process to select and compare the surrogate models further comprises:
utilizing a dual objective pareto optimal surrogate model selection process;
processing assumptions using hyper-parameter optimization before performing the statistical analysis on the input parameters;
utilizing a statistical test to analyze the performance of the surrogate models.

6. The method of claim 5, wherein the dual objective pareto optimal surrogate model selection process is based on root mean square error and a calibration area.

7. The method of claim 1, wherein generating the report including the plurality of uncertainty intervals and future test point recommendations comprises generating the report based on active learning.

8. The method of claim 1, wherein generating the plurality of uncertainty intervals further comprises:
generating a coverage plot bounded over one of the plurality of uncertainty intervals; and
displaying the regression response with associated uncertainty interval on a graphical user interface.

9. A computer system for quantifying uncertainty, said system comprising:
a computing device comprising a processor, said processor configured to:
receive, by an uncertainty quantification computing device, input parameters;
perform, by the uncertainty quantification computing device, a statistical analysis to generate a plurality of uncertainty intervals based on the input parameters;
determine, by the uncertainty quantification computing device, whether the input parameters fall within an accuracy range;
generate, by the uncertainty quantification computing device, a report including the plurality of the uncertainty intervals and a future test point recommendation.

10. The computer system of claim 9, wherein in receiving the input parameters, the processor is configured to:
define simulation output parameters and the accuracy range; and
upload simulation output data and a configuration file.

11. The computer system of claim 9, wherein in performing the statistical analysis to generate a first plurality of uncertainty intervals based on the input parameters, the processor is configured to utilize an automated process to select and compare surrogate models.

12. The computer system of claim 11, wherein the surrogate models further comprise a machine learning algorithm;

13. The computer system of claim 11, wherein in the automated process to select and compare the surrogate models, the processor is configured to:
utilize a dual objective pareto optimal surrogate model selection process;
process assumptions using hyper-parameter optimization before performing the statistical analysis on the input parameters;
utilize a statistical test to analyze the performance of the surrogate models.

14. The computer system of claim 13, wherein the dual objective pareto optimal surrogate model selection process is based on root mean square error and a calibration area.

15. The computer system of claim 9, wherein generating the report including the plurality of uncertainty intervals and future test point recommendations comprises generating the report based on active learning.

16. The computer system of claim 9, wherein in generating the plurality of uncertainty intervals, the processor is configured to:
generate a coverage plot bounded over one of the plurality of uncertainty intervals; and
display the regression response with associated uncertainty interval on a graphical user interface.
